(19) United States
(12) Patent Application Publication
(10) Pub. No.: US 2026/0076165 A1
(43) Pub. Date: Mar. 12, 2026

(54) FRONTSIDE VIA WITHIN SINGLE DIFFUSION BREAK FOR BACKSIDE POWER RAIL

(71) Applicant: INTERNATIONAL BUSINESS MACHINES CORPORATION, ARMONK, NY (US)

(72) Inventors: Lijuan Zou, Albany, NY (US); Tao Li, Slingerlands, NY (US); Ruilong Xie, Niskayuna, NY (US); Ravikumar Ramachandran, Pleasantville, NY (US)

(21) Appl. No.: 18/827,632

(22) Filed: Sep. 6, 2024

(51) Int. Cl. H01L 23/528; H01L 21/8234; H01L 29/06; H01L 29/08

(52) U.S. Cl. CPC H10W 20/427; H10D 62/115; H10D 62/118; H10D 62/151; H10D 84/013; H10D 84/0149; H10D 84/0151; H10D 84/038

(57) ABSTRACT

A semiconductor device can include a first source/drain region, a second source/drain region, a diffusion break between the first source/drain region and the second source/drain region, and an interconnect within the diffusion break and configured to connect a back end of line (BEOL) in a frontside of the semiconductor device to a backside power delivery network (BSPDN) in a backside of the semiconductor device. The interconnect includes a first vertical section, a second vertical section connected to the first vertical section on an upper end of the second vertical section, and a backside section connected to a lower end of the second vertical section, wherein the first vertical section is located on top of the first source/drain.

### BACKGROUND

### Technical Field

The present disclosure generally relates to semiconductors, and more particularly, to semiconductors with frontside via within a single diffusion break (SDB) for backside power rail structure, and methods of creation thereof.

### Description of Related Art

The continuous miniaturization of transistors and their growing density on chips exemplify the semiconductor industry's innovation, largely in line with Moore's Law. This progression has resulted in transistors being reduced to nanometer scales, enabling millions, even billions, to be packed onto a single chip, thereby greatly improving computational power and energy efficiency. The evolution towards system-on-chip architectures further integrates multiple functions, such as processing and sensing, onto a single chip.

### SUMMARY

According to an embodiment, a semiconductor device includes a first source/drain region, a second source/drain region, a diffusion break between the first source/drain region and the second source/drain region, and an interconnect within the diffusion break and configured to connect a back end of line (BEOL) in a frontside of the semiconductor device to a backside power delivery network (BSPDN) in a backside of the semiconductor device. The interconnect includes a first vertical section, a second vertical section connected to the first vertical section on an upper end of the second vertical section, and a backside section connected to a lower end of the second vertical section, wherein the first vertical section is located on top of the first source/drain.

In one embodiment, the second vertical section extends from one side of the first source/drain into the diffusion break, and the backside section extends to the backside of the semiconductor device.

In one embodiment, the first vertical section and the second vertical section are vertically offset from each other.

In one embodiment, the semiconductor device includes shallow trench isolation (STI) on opposite sides of the second vertical section, and a spacer isolating the diffusion break and the second vertical section.

In one embodiment, the semiconductor device includes a cap layer over the second vertical section, and an interlayer dielectric (ILD) isolating the cap layer and the diffusion break from contact with the BEOL.

In one embodiment, the semiconductor device includes a bottom interlayer dielectric (BILD) isolating the BSPDN from contact with the interconnect, and a backside power rail within the BILD and in contact with the BSPDN.

In one embodiment, the semiconductor device includes a gate region, and a plurality of alternating nanosheet gates extending horizontally across the gate region.

According to an embodiment, a method for fabrication of a semiconductor device includes forming a first source/drain region, forming a second source/drain region, forming a diffusion break between the first source/drain region and the second source/drain region, forming an interconnect within the diffusion break, and establishing a connection between a frontside of the semiconductor device and a backside of the semiconductor device via the interconnect.

In one embodiment, forming a first vertical section, forming a second vertical section connected to the first vertical section on an upper end of the second vertical section, and forming a backside section connected to a lower end of the second vertical section, wherein the first vertical section is located on top of the first source/drain.

In one embodiment, the method includes extending the second vertical section from one side of the first source/drain into the diffusion break, and extending the backside section to the backside of the semiconductor device.

In one embodiment, the first vertical section and the second vertical section are offset from each other.

In one embodiment, the method includes forming a shallow trench isolation (STI) on opposite sides of the second vertical section, and isolating the diffusion break and the second vertical section via a spacer.

In one embodiment, the method includes forming a cap layer over the second vertical section, and isolating the cap layer and the diffusion break from contact with the BEOL via an interlayer dielectric (ILD).

In one embodiment, the method includes isolating the BSPDN from contact with the interconnect via a bottom interlayer dielectric (BILD), and forming a backside power rail within the BILD and in contact with the BSPDN.

In one embodiment, the method includes forming a gate region, and forming a plurality of alternating nanosheet gates extending horizontally across the gate region.

According to an embodiment, a semiconductor device includes a first source/drain region, a second source/drain region, a single diffusion break (SDB) between the first source/drain region and the second source/drain region, and a frontside via within the SDB. One side of frontside via is connected to a frontside contact over the first source/drain region, and the frontside via is connected to a backside power delivery network (BSPDN).

In one embodiment, the frontside via is connected to the BSPDN through a backside via and a backside power rail (BPR).

In one embodiment, the semiconductor device includes shallow trench isolation (STI) on opposite sides of the frontside via, and a spacer isolating the SDB and the frontside via.

In one embodiment, the semiconductor device includes a cap layer over the frontside via, and an interlayer dielectric (ILD) isolating the cap layer and the SDB from contact with a back end of line (BEOL).

In one embodiment, the semiconductor device includes a bottom interlayer dielectric (BILD) isolating the BSPDN from contact with the frontside via, and a backside power rail within the BILD and in contact with the BSPDN.

These and other features will become apparent from the following detailed description of illustrative embodiments thereof, which is to be read in connection with the accompanying drawings.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIG. 1A illustrates a semiconductor device with a diffusion break for backside power rail, in accordance with an embodiment.

FIG. 1B illustrates a top view of a semiconductor device, in accordance with an embodiment.

FIG. 2A illustrates a semiconductor device after the formation of the source/drain regions, in accordance with an embodiment.

FIG. 2B illustrates a top view of a semiconductor device after the formation of the source/drain regions, in accordance with an embodiment.

FIG. 3A illustrates a semiconductor device after the patterning of the single diffusion break, in accordance with an embodiment.

FIG. 3B illustrates a top view of a semiconductor device after the patterning of the single diffusion break, in accordance with an embodiment.

FIG. 4A illustrates a semiconductor device after the patterning of the frontside via, in accordance with an embodiment.

FIG. 4B illustrates a top view of a semiconductor device after the patterning of the frontside via, in accordance with an embodiment.

FIG. 5A illustrates a semiconductor device after the formation of the inner spacer, in accordance with an embodiment.

FIG. 5B illustrates a top view of a semiconductor device after the formation of the inner spacer, in accordance with an embodiment.

FIG. 6A illustrates a semiconductor device after the metallization of the frontside via, in accordance with an embodiment.

FIG. 6B illustrates atop view of a semiconductor device after the metallization of the frontside via, in accordance with an embodiment.

FIG. 7A illustrates a semiconductor device after the middle of line processes, in accordance with an embodiment.

FIG. 7B illustrates a top view of a semiconductor device after the middle of line processes, in accordance with an embodiment.

FIG. 8A illustrates a semiconductor device after the patterning of the spacer, in accordance with an embodiment.

FIG. 8B illustrates a top view of a semiconductor device after the patterning of the spacer, in accordance with an embodiment.

FIG. 9A illustrates a semiconductor device after the back end of line processes, in accordance with an embodiment.

FIG. 9B illustrates a top view of a semiconductor device after the back end of line processes, in accordance with an embodiment.

FIG. 10 illustrates a semiconductor device after the removal of the substrate, in accordance with an embodiment.

FIG. 11 illustrates a semiconductor device after the removal of the etch stop layer, in accordance with an embodiment.

FIG. 12 illustrates a semiconductor device after the patterning of the backside via, in accordance with an embodiment.

FIG. 13 illustrates a semiconductor device after the formation of the backside via dielectric liner, in accordance with an embodiment.

FIG. 14 illustrates a semiconductor device after the metallization of the backside via, in accordance with an embodiment.

FIG. 15 illustrates a semiconductor device after the formation of the backside power delivery network, in accordance with an embodiment.

FIG. 16 illustrates a block diagram of a method for forming the semiconductor device, in accordance with some embodiments.

### DETAILED DESCRIPTION

### Overview

In the following detailed description, numerous specific details are set forth by way of examples to provide a thorough understanding of the relevant teachings. However, it should be apparent that the present teachings may be practiced without such details. In other instances, well-known methods, procedures, components, and/or circuitry have been described at a relatively high-level, without detail, to avoid unnecessarily obscuring aspects of the present teachings.

In one aspect, spatially related terminology such as “front,” “back,” “top,” “bottom,” “beneath,” “below,” “lower,” above,” “upper,” “side,” “left,” “right,” and the like, is used with reference to the orientation of the Figures being described. Since components of embodiments of the disclosure can be positioned in a number of different orientations, the directional terminology is used for purposes of illustration and is in no way limiting. Thus, it will be understood that the spatially relative terminology is intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as below. The device may be otherwise oriented (rotated 90 degrees or viewed or referenced at other orientations) and the spatially relative descriptors used herein should be interpreted accordingly.

As used herein, the terms “lateral” and “horizontal” describe an orientation parallel to a first surface of a chip.

As used herein, the term “vertical” describes an orientation that is arranged perpendicular to the first surface of a chip, chip carrier, or semiconductor body. The term “offset” generally refers to the amount by which a component is out of line or placed out of its position relative to another reference point or line, which can indicate a displacement or deviation from a designated alignment, path, or position. Such a deviation can be measured in any direction—horizontal, vertical, or along any diagonal or arbitrary axis, depending on the specific context in which it is used.

As used herein, the terms “coupled” and/or “electrically coupled” are not meant to mean that the elements must be directly coupled together—intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together.

Although the terms first, second, etc., may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments may be used and structural or logical changes may be made without departing from the spirit and scope defined by the claims. The description of the embodiments is not limiting. In particular, elements of the embodiments described hereinafter may be combined with elements of different embodiments.

According to an embodiment, a semiconductor device includes a first source/drain region, a second source/drain region, a diffusion break between the first source/drain region and the second source/drain region, and an interconnect within the diffusion break and configured to connect a back end of line (BEOL) in a frontside of the semiconductor device to a backside power delivery network (BSPDN) in a backside of the semiconductor device. The interconnect includes a first vertical section, a second vertical section connected to the first vertical section on an upper end of the second vertical section, and a backside section connected to a lower end of the second vertical section, wherein the first vertical section is located on top of the first source/drain. Thus, the interconnect connects the frontside to the backside within the single diffusion break (SDB).

In one embodiment, which can be combined with the previous embodiment, the second vertical section extends from one side of the first source/drain into the diffusion break, and the backside section extends to the backside of the semiconductor device. The interconnect can include the frontside contact and a deep via from the frontside to the backside of the semiconductor device.

In one embodiment, which can be combined with the previous embodiment, the first vertical section and the second vertical section are offset from each other. Such an offset can ensure that the first vertical section is in contact with the SDB and has enough contact area. The bigger the contact area, the smaller the contact resistance, which is desired for device performance.

In one embodiment, which can be combined with the previous embodiment, the semiconductor device includes shallow trench isolation (STI) on opposite sides of the second vertical section, and a spacer isolating the diffusion break and the second vertical section. Thus, the SDB and the interconnect are not electrically connected to avoid shorting.

In one embodiment, which can be combined with the previous embodiment, the semiconductor device includes a cap layer over the second vertical section, and an interlayer dielectric (ILD) isolating the cap layer and the diffusion break from contact with the BEOL. Thus, the SDB and the BEOL are not electrically connected.

In one embodiment, which can be combined with the previous embodiment, the semiconductor device includes a bottom interlayer dielectric (BILD) isolating the BSPDN from contact with the interconnect, and a backside power rail within the BILD and in contact with the BSPDN. Thus, the BSPDN and the interconnect are not electrically connected.

In one embodiment, which can be combined with the previous embodiment, the semiconductor device includes a gate region, and a plurality of alternating nanosheet gates extending horizontally across the gate region. The semiconductor device can be a nanosheet transistor.

According to an embodiment, a method for fabrication of a semiconductor device includes forming a first source/drain region, forming a second source/drain region, forming a diffusion break between the first source/drain region and the second source/drain region, forming an interconnect within the diffusion break, and establishing a connection between a frontside of the semiconductor device and a backside of the semiconductor device via the interconnect. Thus, the interconnect connects the frontside to the backside within the diffusion break.

In one embodiment, which can be combined with the previous embodiment, forming a first vertical section, forming a second vertical section connected to the first vertical section on an upper end of the second vertical section, and forming a backside section connected to a lower end of the second vertical section, wherein the first vertical section is located on top of the first source/drain. The interconnect can include the multiple sections extended from the frontside to the backside of the semiconductor device.

In one embodiment, which can be combined with the previous embodiment, the method includes extending the second vertical section from one side of the first source/drain into the diffusion break, and extending the backside section to the backside of the semiconductor device. Thus, the interconnect can electrically connect various components on the frontside and the backside of the semiconductor device.

In one embodiment, which can be combined with the previous embodiment, the first vertical section and the second vertical section are offset from each other. Such an offset can ensure that the first vertical section is in contact with the SDB and has enough contact area. The bigger the contact area, the smaller the contact resistance, which is desired for device performance.

In one embodiment, which can be combined with the previous embodiment, the method includes forming shallow trench isolation (STI) on opposite sides of the second vertical section, and isolating the diffusion break and the second vertical section via a spacer. Thus, the diffusion break and the interconnect are not electrically connected to avoid shorting.

In one embodiment, which can be combined with the previous embodiment, the method includes f forming a cap layer over the second vertical section, and isolating the cap layer and the diffusion break from contact with the BEOL via an interlayer dielectric (ILD). Thus, the diffusion break and the BEOL are not electrically connected.

In one embodiment, which can be combined with the previous embodiment, the method includes isolating the BSPDN from contact with the interconnect via a bottom interlayer dielectric (BILD), and forming a backside power rail within the BILD and in contact with the BSPDN. Thus, the BSPDN and the interconnect are not electrically connected.

In one embodiment, which can be combined with the previous embodiment, the method includes forming a gate region, and forming a plurality of alternating nanosheet gates extending horizontally across the gate region. The semiconductor device can be a nanosheet transistor.

According to an embodiment, a semiconductor device includes a first source/drain region, a second source/drain region, a single diffusion break (SDB) between the first source/drain region and the second source/drain region, and a frontside via within the SDB. One side of frontside via is connected to a frontside contact over the first source/drain region, and the frontside via is connected to a backside power delivery network (BSPDN). Thus, the interconnect connects the frontside to the backside within the SDB.

In one embodiment, which can be combined with the previous embodiment, the frontside via is connected to the BSPDN through a backside via and a backside power rail (BPR). The frontside via can electrically connect the frontside of the semiconductor device to the backside.

In one embodiment, which can be combined with the previous embodiment, the semiconductor device includes shallow trench isolation (STI) on opposite sides of the frontside via, and a spacer isolating the SDB and the frontside via. The SDB and the frontside via are not electrically connected toa void shorting.

In one embodiment, which can be combined with the previous embodiment, the semiconductor device includes a cap layer over the frontside via, and an interlayer dielectric (ILD) isolating the cap layer and the SDB from contact with a back end of line (BEOL). Thus, the diffusion break and the BEOL are not electrically connected.

In one embodiment, which can be combined with the previous embodiment, the semiconductor device includes a bottom interlayer dielectric (BILD) isolating the BSPDN from contact with the frontside via, and a backside power rail within the BILD and in contact with the BSPDN. Thus, the BSPDN and the interconnect are not electrically connected.

Disclosed semiconductor device utilizes an interconnect to connect the frontside of the device to the backside of the device, while forming within a single diffusion break (SDB). In the context of a backside power delivery network that utilizes a fully via-based power (FVBP) scheme, the presence of a single diffusion break (SDB) can offer an advantage in the design and optimization of the transistor. Specifically, in the presence of an SDB, it is advantageous to construct a frontside via within the SDB region itself. The disclosed semiconductor device places the frontside via within the SDB, which enables repurposing the conventional area typically allocated for frontside vias to other functions. One of the uses of this freed-up area is to facilitate connections between the frontside and backside of the device. This capability is particularly valuable because it enables direct and efficient routing of signals and power between the different layers of the semiconductor device.

Incorporating the frontside-to-backside connections can lead to improvements in device performance. For instance, by optimizing the routing and minimizing the distances that signals need to travel, the overall resistance and capacitance in the device can be reduced. This reduction translates to faster signal propagation, lower power consumption, and improved thermal management, all of which contribute to enhanced performance of the semiconductor device. Moreover, the ability to use the conventional via area for the additional connections allows for greater design flexibility and potentially more complex and capable device architectures. By strategically utilizing the space within the SDB for the frontside via, the disclosed semiconductor device can facilitate maximizing the efficiency of the power delivery network while also enhancing the overall functionality and performance of the device.

Accordingly, the teachings herein provide methods and systems of semiconductor device formation with. The techniques described herein may be implemented in a number of ways. Example implementations are provided below with reference to the following figures.

### Example Semiconductor Device with Frontside Via within an SDB Structure

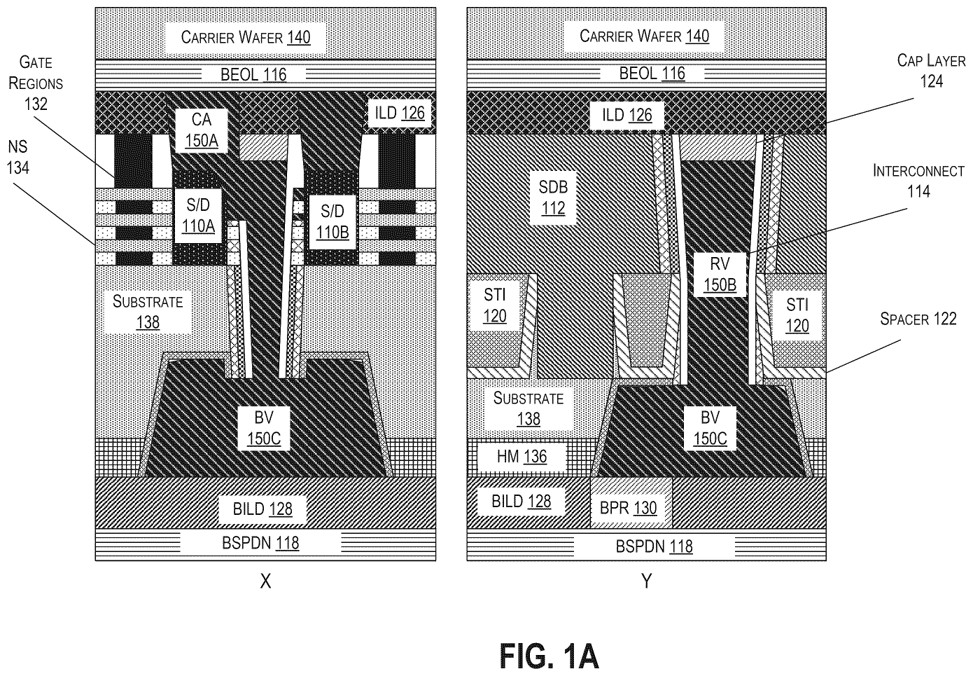

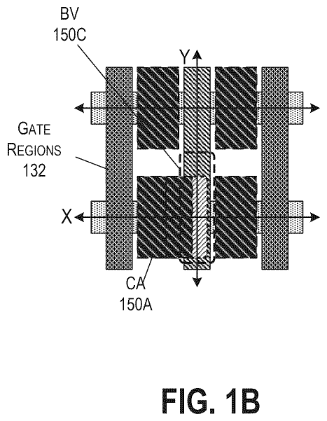

Reference now is made to FIG. 1A, which is a simplified cross-section view of a semiconductor device with frontside via and SDB structure, consistent with illustrative embodiments. FIG. 1B illustrates a top view of the semiconductor device shown in FIG. 1A. As shown, the sections denoted as X and Y represent different cross-sections of the semiconductor device. Figures denoted by B depicts the X and Y cross-sections from a top view. Referring to FIG. 1A now, the semiconductor device can include a first source/drain region 110A, a second source/drain region 110B, a diffusion break, SDB 112, an interconnect 114, a back end of line, BEOL 116, a backside power delivery network, BSPDN 118, shallow trench isolation, STI 120, a spacer 122, a cap layer 124, an interlayer dielectric, ILD 126, a bottom interlayer dielectric, BILD 128, a backside power rail, BPR 130, gate regions 132, a plurality of alternating nanosheet gates, NS 134, a hard mask, HM 136, a substrate 138, and a carrier wafer 140.

Generally, the first source/drain region 110A and the second source/drain region 110B, are components that play salient roles in the semiconductor device's operation. In various embodiments, the first source/drain region 110A and the second source/drain region 110B, are region within the semiconductor material, e.g., the semiconductor device, where the current flows in and out of the semiconductor device. The source region is the region through which the majority of charge carriers (e.g., electrons or holes) enter the channel of the semiconductor device and is responsible for providing the current that flows through the semiconductor device. The source region is typically doped to have an excess of charge carriers, creating a region with high carrier concentration. This abundance of carriers allows for the efficient injection of electrons or holes into the channel when a voltage is applied.

The drain region, on the other hand, is the region where the majority of charge carriers exit the channel. The drain region receives the current from the channel and carries the charge away from the transistor. Similar to the source, the drain region is also doped to have a high carrier concentration. The doping profile in the drain region ensures that carriers can easily flow out of the channel and into the drain region.

The SDB 112 can enhance the performance and efficiency of the semiconductor device. By controlling the diffusion of dopants to a single, abrupt change in concentration, the SDB 112 can allow for a sharper definition of the channel edges. This helps in reducing short-channel effects, which are detrimental phenomena that occur when the channel length of the semiconductor device is comparable to the depletion layers extending from the source and drain junctions. Short-channel effects can lead to issues such as threshold voltage lowering and drain-induced barrier lowering, both of which degrade the transistor's performance. Additionally, the SDB 112 can improve the semiconductor's drive current capability and reduce leakage currents, leading to a more power-efficient semiconductor device. In some embodiments, the SDB 112 can be located between the first source/drain region 110A and the second source/drain region 110B to control the dopant profile, reduce electrical leakage, and enhance the semiconductor performance.

Within this SDB 112, the interconnect 114 can link different parts of the semiconductor device. The interconnect 114 can include a first vertical section 150A, CA, above the first source/drain region 110A, initiating the connection from the frontside of the semiconductor device. A second vertical section 150B, RV, reaching down to the backside of the semiconductor device, connecting to the BSPDN 118. The pathway is completed by a backside section 150C, BV, that interfaces with components on the semiconductor's backside to facilitate power delivery.

The first vertical section 150A acts as a frontside contact and is positioned directly above the first source/drain region 110A. This placement can facilitate effective electrical conduction from the frontside to other parts of the semiconductor device. The first vertical section 150A, e.g., the frontside contact, can establish a connection between first source/drain region 110A and the BEOL 116. The first vertical section 150A, e.g., the frontside contact, can ensure efficient electrical routing and connectivity within the semiconductor device. The fabrication of the first vertical section 150A, e.g., the frontside contact, can involve lithography and etching processes to define the contact area. The frontside contact can be made using conductive materials such as copper (Cu) or tungsten (W).

In some embodiments, the second vertical section 150B can function as a frontside via within the SDB 112. The second vertical section 150B serves as a conduit for electrical connections across the semiconductor device. Specifically, one side of the second vertical section 150B, also known as the frontside via, is connected to the first vertical section 150A.

In some embodiments, the connection of the first vertical section 150A, e.g., the frontside via, extends further to interface with the BSPDN 118. This can be achieved through the continuation into the second vertical section 150B and connecting to the backside section 150C. The backside section 150C, e.g., the backside via, can provide the pathway for linking the frontside of the semiconductor device to the BSPDN 118 located at the backside. This comprehensive setup can ensure a robust and efficient electrical connectivity throughout the semiconductor device, allowing for enhanced functionality and performance in various applications. In some embodiments, while the first vertical section 150A is located over the first source/drain region 110A, the second vertical section 150B is located between the first source/drain region 110A and the second source/drain region 110B. As such, in some embodiments, the first vertical section 150A and the second vertical section 150B are offset from each other.

The backside section 150C, e.g., the backside via, can be a region on the backside of the semiconductor device where electrical connections are made. By establishing the electrical contacts, the backside section 150C can ensure the proper functioning of the semiconductor device and facilitates electrical signal transmission. The backside section 150C can serve as a thermal interface between the semiconductor device and a heat sink or other cooling mechanisms. By establishing direct contact with the substrate, the backside section 150C can conduct the heat away from the semiconductor device, and contribute to improved thermal dissipation. In some embodiments, the backside section 150C can help mitigate parasitic effects, such as substrate coupling or substrate noise, from the semiconductor device. In further embodiments, the backside section 150C can allow for increased integration density in the semiconductor device.

The BEOL 116 can include metal interconnects and other structures on the upper layers of the semiconductor device to form a network of connections that link various components of the semiconductor device.

The BSPDN 118 can distribute power efficiently across the semiconductor device from the backside, which can complement the vertical architecture by saving lateral space.

The STI 120 can electrically isolate different components by filling the trenches with an insulating material, such as silicon dioxide. The STI 120 can prevent electrical interference and crosstalk between adjacent devices, ensuring that each component operates independently without affecting its neighbors. In some embodiments, the STI 120 includes an STI liner and an STI oxide.

To ensure that each section functions independently without electrical interference, the STI 120 is placed on either side of the backside section 150C, and the spacer 122 isolates the SDB 112 from the second vertical section 150B. These isolation features can facilitate maintaining the integrity and functionality of the interconnect 114 by reducing potential electrical crosstalk and leakage.

The spacer 122 can cover, e.g., surround, the first source/drain region 110A. In some embodiments, the spacer 122 can isolate the STI 120 from contact with the gate regions 132. The cap layer 124 can cover the second vertical section 150B, providing protection against environmental and processing stresses. The ILD 126 separates the cap layer 124 from the BEOL 116 to prevent electrical shorts.

In the backside of the semiconductor device, the BILD 128 isolates the BSPDN 118 from the interconnect 114 to ensure that power delivery does not interfere with the interconnect's functionality. The BPR 130 within the BILD 128 can facilitate efficient power distribution across the backside, enhancing the semiconductor device operation.

At the core of semiconductor device's operation, the gate regions 132 control carrier flow within the semiconductor's channel. The gate regions 132 serve as control elements that regulate the flow of current through the semiconductor device. The gate regions 132 can be composed of a conductive material. The gate regions 132 can control the flow of electric current across the channel region. In addition to acting as a switch, modulating the gate voltage can enable the gate regions 132 to control the current flowing through the channel region, resulting in amplified output signals.

In an embodiment, the gate regions 132 can enable the implementation of Boolean active operations, such as AND, OR, and NOT, by controlling the flow of current based on the input voltages. In some embodiments, the gate regions 132, along with other active device components, can facilitate the miniaturization and integration of electronic circuits. The ability to control the channel region's conductivity through the gate voltage allows for compact and highly efficient circuit designs.

The NS 134, which can consist of conductive and insulating materials, extends horizontally across the gate regions 132. The NS 134 allows for control over the channel, improving the electrical performance and scalability of the semiconductor device.

The carrier wafer 140 can be used to support the wafers and avoid damages during processing, as handling and processing wafers without additional support can lead to breakage or warping, especially during high-temperature or precision processes. The carrier wafer 140 can function as mechanical supports.

### Example Fabrication of a Semiconductor Device with Frontside Via within an SDB

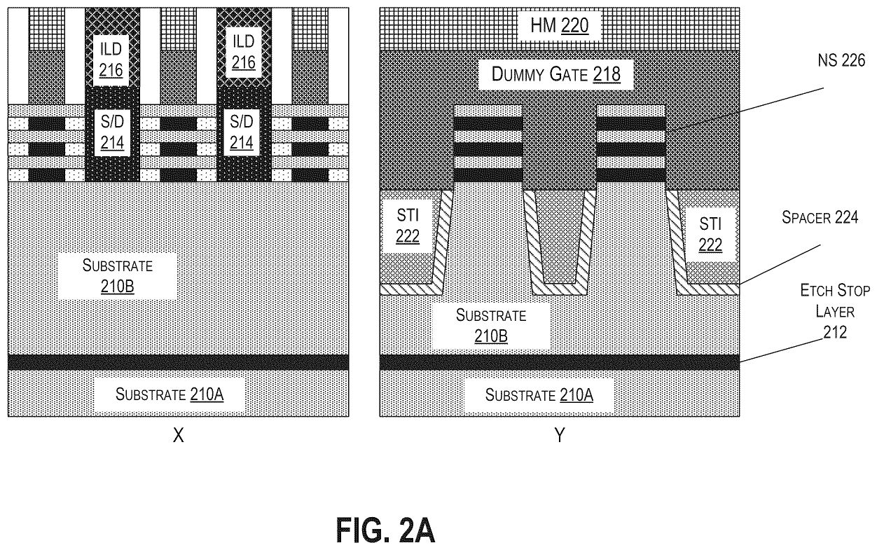

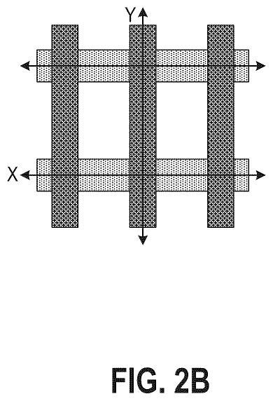

With the foregoing description of an example semiconductor device, it may be helpful to discuss an example process of manufacturing the same. To that end, FIGS. 2-15 illustrate various acts in the manufacture of a semiconductor device, consistent with illustrative embodiments. As noted above, figures denoted by A illustrate the cross-section views of the semiconductor device, and figures denoted by B illustrates top views of the semiconductor device.

Reference now is made to FIG. 2A, which is a simplified cross-section view of a semiconductor device, after the formation of the source/drain regions, consistent with an illustrative embodiment. In some embodiments, after the formation of the source/drain regions, the semiconductor device includes a first substrate 210A, a second substrate 210b, an etch stop layer 212, source/drain regions, S/D 214, ILD 216, dummy gate 218, gate hard masks, HM 220, STI 222, a spacer 224, and NS 226.

In the illustrative example depicted in FIGS. 2A-2B, the semiconductor device is depicted as being on silicon as the first substrate 210A and the second substrate 210B, while it will be understood that other types as the first substrate 210A and the second substrate 210B can be used as well, including, without limitation, monocrystalline Si, silicon germanium (SiGe), III-V compound semiconductor, II-VI compound semiconductor, or semiconductor-on-insulator (SOI). Group III-V compound semiconductors, for example, include materials having at least one group III element and at least one group V element, such as one or more of aluminum gallium arsenide (AlGaAs), aluminum gallium nitride (AlGaN), aluminum arsenide (AlAs), aluminum indium arsenide (AlIAs), aluminum nitride (AlN), gallium antimonide (GaSb), gallium aluminum antimonide (GaAlSb), gallium arsenide (GaAs), gallium arsenide antimonide (GaAsSb), gallium nitride (GaN), indium antimonide (InSb), indium arsenide (InAs), indium gallium arsenide (InGaAs), indium gallium arsenide phosphide (InGaAsP), indium gallium nitride (InGaN), indium nitride (InN), indium phosphide (InP) and alloy combinations including at least one of the foregoing materials. The alloy combinations can include binary (two elements, e.g., gallium (III) arsenide (GaAs)), ternary (three elements, e.g., InGaAs), and quaternary (four elements, e.g., aluminum gallium indium phosphide (AlInGaP)) alloys.

In various embodiments, the first substrate 210A and the second substrate 210B can include any suitable material or combination of materials, such as doped or undoped silicon, glass, dielectrics, etc. For example, the substrate may include a silicon-on-insulator (SOI) structure, e.g., with a buried insulator layer, or a bulk material substrate, e.g., with appropriately doped regions, typically referred to as wells. In another embodiment, the substrate may be silicon with silicon oxide, nitride, or any other insulating film on top.

In various embodiments, the etch stop layer 212 is formed between the first substrate 210A and the second substrate 210B. The etch stop layer 212 can be a thin layer of material incorporated into the structure of the semiconductor device to provide a selective barrier against etching processes, preventing further removal of underlying materials during fabrication. The etch stop layer 212 can enable precise control over the etching depth and help define the desired device dimensions. The etch stop layer 212 can further provide a stopping point for the etching process, ensuring that specific layers or regions are not etched beyond a certain point, leading to accurate patterning and control of critical features. The etch stop layer 212 can create a distinct separation between different layers or components within the device structure, and prevent the undesired etching of underlying layers or materials, enabling the creation of complex, multi-layered structures with well-defined interfaces and boundaries. In some embodiments, the etch stop layer 212 acts as a protective barrier for sensitive or delicate materials to shield such materials from aggressive etchants, preventing damage or degradation during subsequent fabrication steps.

In some embodiments, prior to forming the etch stop layer 212, the first substrate 210A and/or the second substrate 210B is prepared by cleaning and removing any impurities or oxide layers. The etch stop layer 212 is deposited onto the first substrate 210A using techniques such as chemical vapor deposition (CVD), physical vapor deposition (PVD), or atomic layer deposition (ALD). In an embodiment, a photoresist can be applied, exposed to a patterned mask, developed, and used as a protective layer to define the etch stop regions. The etch stop layer 212 can then be selectively etched, stopping at a predetermined depth, while protecting the underlying layers. After the etching process, the remaining photoresist can be removed through stripping techniques. While in some embodiments, SiGe is used to form the etch stop layer 212, in some embodiments, silicon nitride (SiN), silicon oxide (SiO2), or silicon oxynitride (SiON) can be used as the etch stop layer 212.

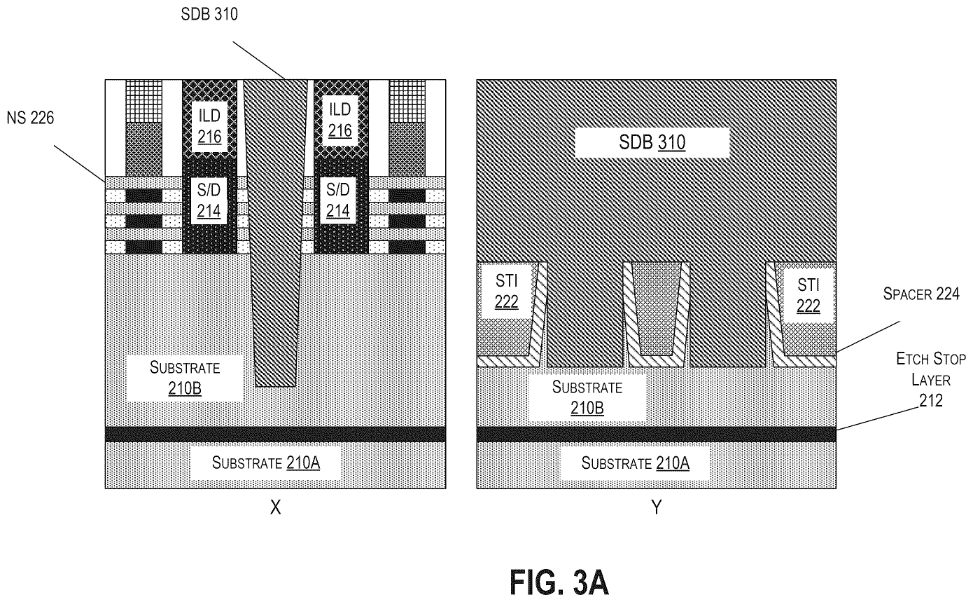

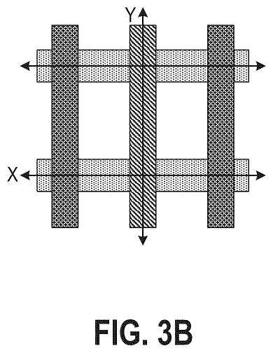

FIG. 3A illustrates the semiconductor device after the patterning of the single diffusive break, in accordance with some embodiments. In some embodiments, the HM, dummy gates, and portions of the nanosheets gates and STI are removed to form the SDB 310. In some embodiments, the SDB 310 can penetrate into the second substrate 212B. FIG. 3B illustrates a top view of the semiconductor device after the patterning of the single diffusive break, in accordance with some embodiments.

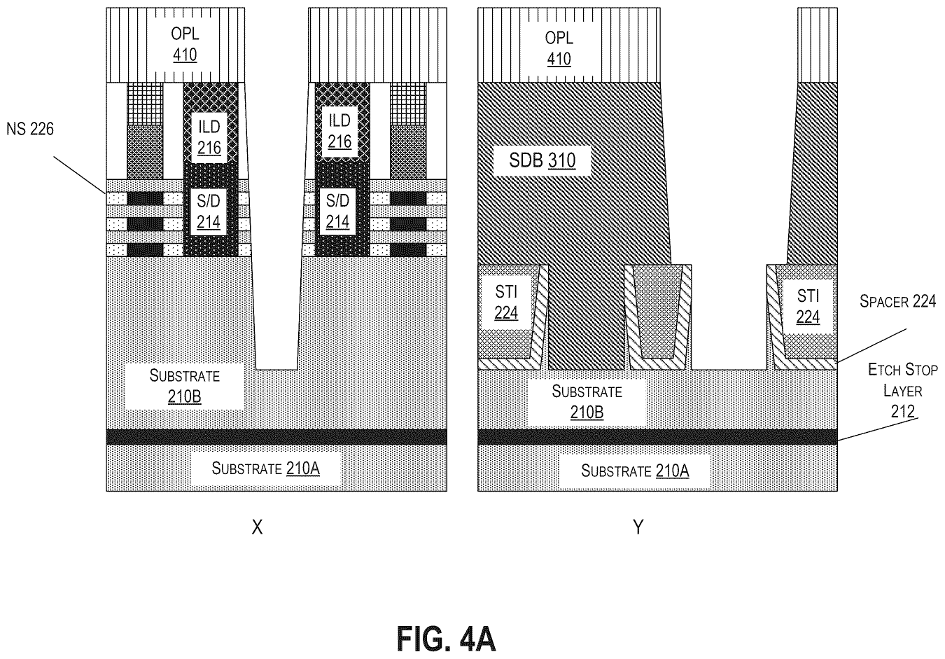

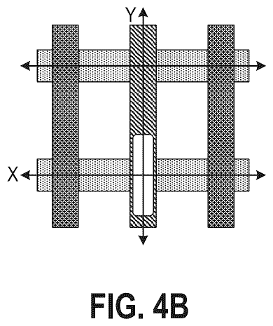

FIG. 4A illustrates the semiconductor device after the patterning of the deep via, in accordance with some embodiments. In some embodiments, an organic planarization layer, OPL 410 is formed over the semiconductor device. ON top of the OPL 410, can be a a photo-sensitive organic polymer (not shown) having a light-sensitive material that, when exposed to electromagnetic radiation, is chemically altered and thus configured to be removed using a developing solvent. For example, in some embodiments, the photo-sensitive organic polymer can be polyacrylate resin, epoxy resin, phenol resin, polyamide resin, polyimide resin, unsaturated polyester resin, polyphenylene ether resin, polyphenylene sulfide resin, or benzo-cyclobutene (BCB). In some embodiments, the OPL 410 can include any organic polymer and a photoactive compound having a molecular structure that can attach to the molecular structure of the organic polymer. In some embodiments, the OPL 410 material is selected to be compatible with an overlying antireflective coating (not shown) and/or an overlying photoresist (not shown). In some embodiments, the OPL 410 can be applied using spin coating technology, although other techniques are within the contemplated scope of the present disclosure. In some embodiments, portions of the OPL 410, SDB 310, and the second substrate 212B are removed to pattern the deep via, followed by a CMP to planarize the semiconductor device. FIG. 4B illustrates a top view of the semiconductor device after the patterning of the deep via, in accordance with some embodiments.

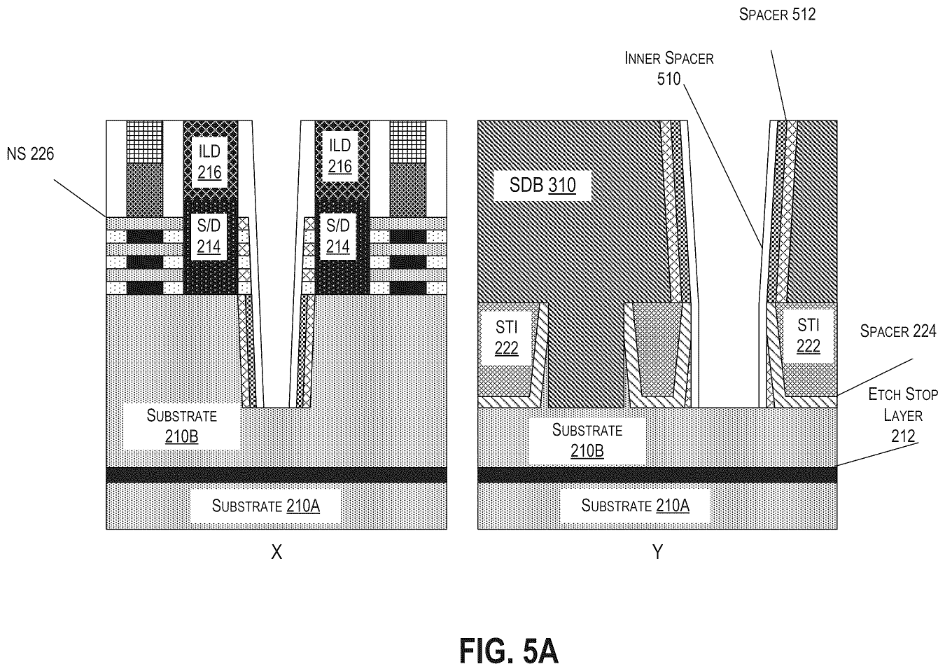

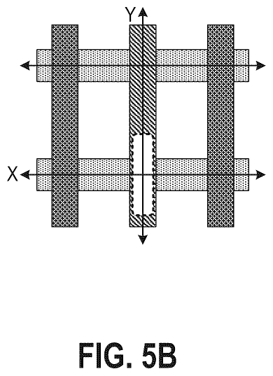

FIG. 5A illustrates the semiconductor device after the formation of the inner spacer, in accordance with some embodiments. In some embodiments, the OPL is removed. A layer of inner spacer 510 and a layer of spacer 512 are deposited over the sidewalls of the cavity that is formed by patterning the deep via. FIG. 5B illustrates a top view of the semiconductor device after the formation of the inner spacer, in accordance with some embodiments.

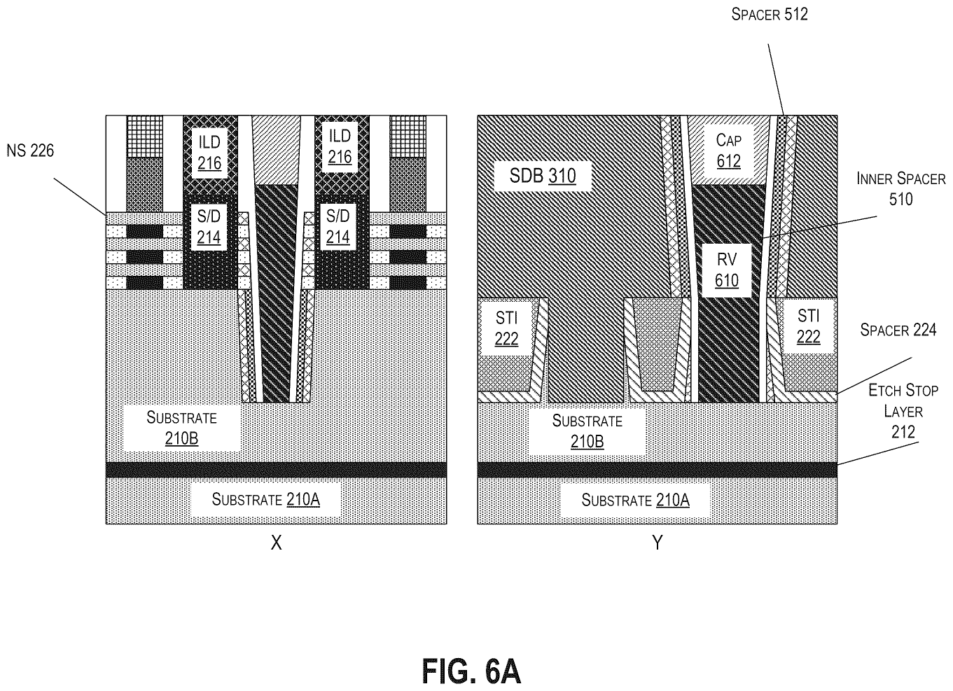

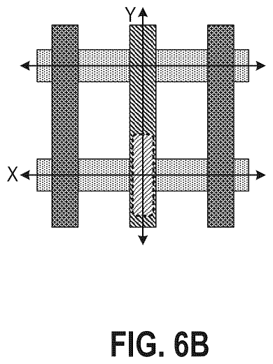

FIG. 6A illustrates the semiconductor device after the metallization of the deep via, in accordance with some embodiments. In some embodiments, portions of the cavity are filled with a suitable metal to form the deep via, RV 610. A capping layer, cap 612, is formed over the RV 610. FIG. 6B illustrates a top view of the semiconductor device after the metallization of the deep via, in accordance with some embodiments.

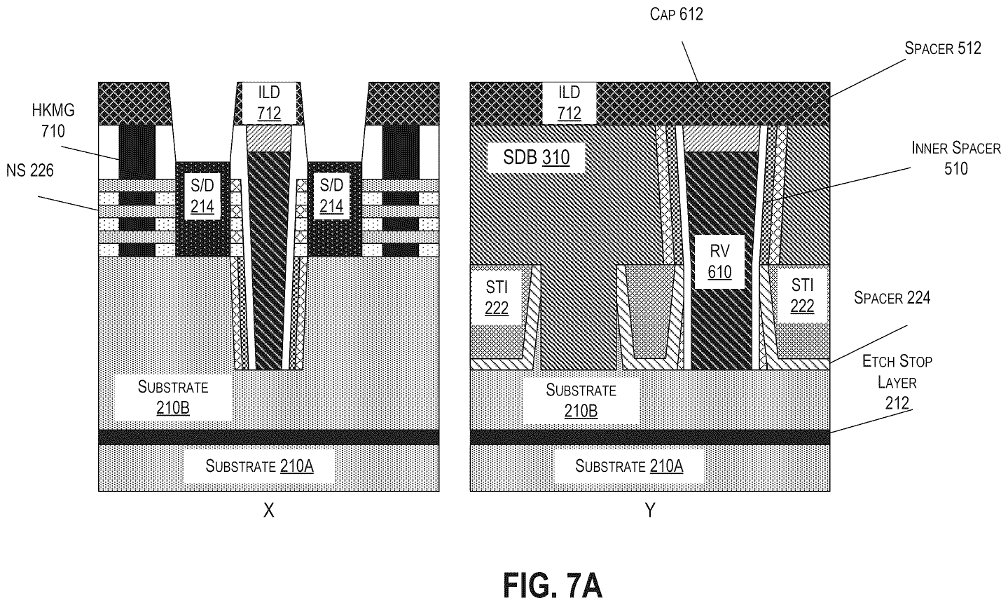

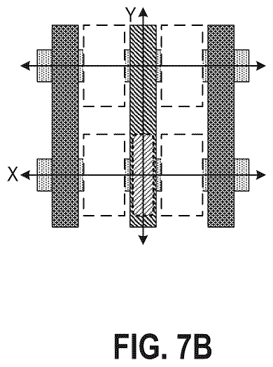

FIG. 7A illustrates the semiconductor device after the middle of line processes, in accordance with some embodiments. In some embodiments, the ILD and the HM are removed, and a replacement gate metallization (RMG) process is performed to form the gate channel, HKMG 710. In some embodiments, the RMG can involve the replacement of the SiGe with a metal material, which can offer improved electrical performance and scalability. The metal gates can provide electrostatic control of the channel region, reduce leakage currents, and improve the semiconductor device's performance. In some embodiments, the metal gates can further provide improved control over the work function, enable matching of threshold voltages, and reduce semiconductor device variability. A layer of ILD 712 can be formed over the SDB 310 and the gate regions. The ILD 712 can be a layer of insulating material to electrically isolate and provide mechanical support between different layers of conducting and active components. The ILD 712 can enable efficient signal transmission, reduce crosstalk, and ensure the proper functioning of semiconductor device. In an embodiment, the ILD 712 can electrically isolate adjacent conducting layers or active components. By providing insulation between different layers, the ILD 712 can prevent electrical shorts, reduce (e.g., minimize) leakage current, and ensure that signals are directed only along the desired pathways. In some embodiments, the ILD 712 can help reduce parasitic capacitance between adjacent metal interconnects or active devices and provide mechanical support to the passive device's structure. FIG. 7B illustrates a top view of the semiconductor device after the middle of line processes, in accordance with some embodiments.

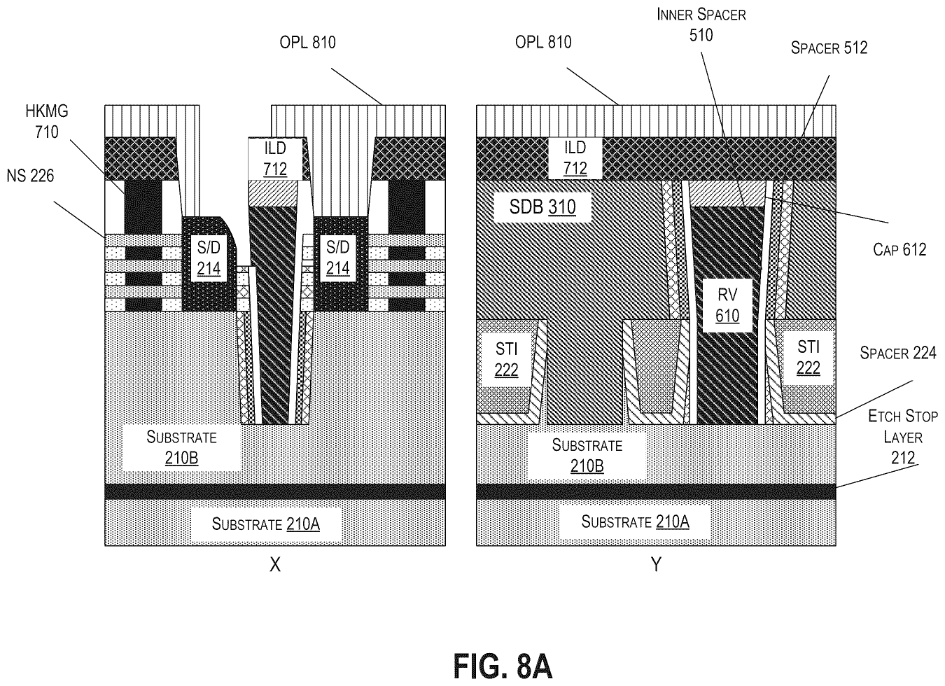

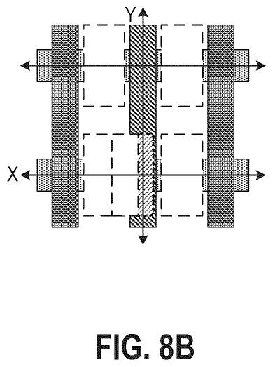

FIG. 8A illustrates the semiconductor device after the formation of an organic planarization layer, in accordance with some embodiments. In some embodiments, an OPL 810 is formed over the semiconductor device. Portions of the OPL 810 above one of the S/D 214 and the RV 610 are removed to pattern the spacer. The spacer next to RV and CAP will then be removed by wet etch or selective dry etch for forming middle of line contact. FIG. 8B illustrates a top view of the semiconductor device after the formation of an organic planarization layer, in accordance with some embodiments.

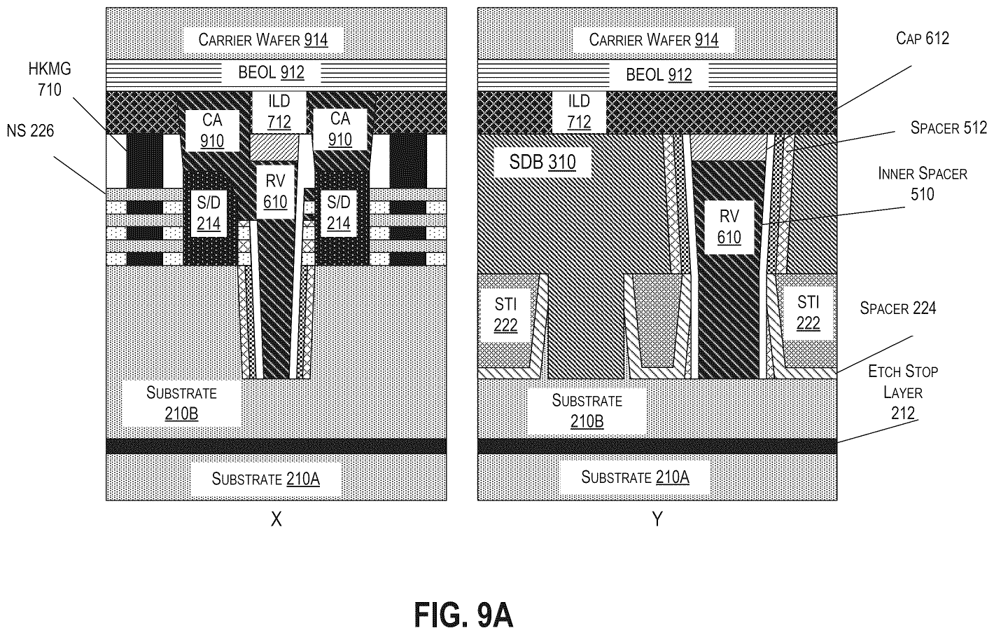

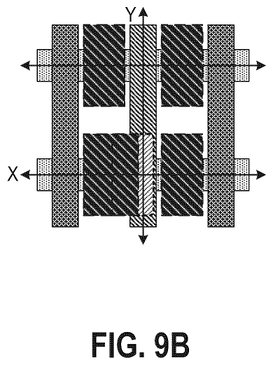

FIG. 9A illustrates the semiconductor device after the back end of line processes, in accordance with some embodiments. In some embodiments, frontside contacts, CA 910, are formed over the S/D 214. One CA 910 can act as the first vertical part of the interconnect. The lower portion of the CA 910 is extended horizontally to connect to the RV 610. In some embodiments, the BEOL 912 is formed over the ILD 712, followed by formation of the carrier wafer 914. The BEOL 912 can include metal interconnects, e.g., wires and metal lines, and insulating layers that connect the various components of the semiconductor device and enable them to function as a cohesive unit.

In various embodiments, carrier wafer bonding, also known as wafer-to-wafer bonding or chip-to-wafer bonding, is performed to join two semiconductor devices together by creating a permanent bond between them. In some embodiments, the two semiconductor devices can be brought into contact and bonded at the atomic or molecular level, to create an interface. In an embodiment, the two semiconductor devices are brought into contact under controlled conditions, such as controlled pressure and temperature, to enable atomic or molecular bonding at the interface. Such bonding can be done at room temperature or with elevated temperatures. Alternatively, in some embodiments, an electric field and elevated temperature are utilized to create a bond. One semiconductor device can be made of semiconductor material, while the other can be a glass or silicon dioxide (SiO2) wafer. The electric field can cause ions in the glass or SiO2 to migrate and chemically bond with the semiconductor material in the other semiconductor device. In additional embodiments, a thin metal layer or metal alloy can be used as an intermediate bonding layer between the semiconductor devices. The metal layer can be deposited or transferred onto one or both semiconductor device surfaces, and the semiconductor devices can then be brought into contact and subjected to temperature and pressure to create a metallic bond. FIG. 9B illustrates a top view of the semiconductor device after the back end of line processes, in accordance with some embodiments.

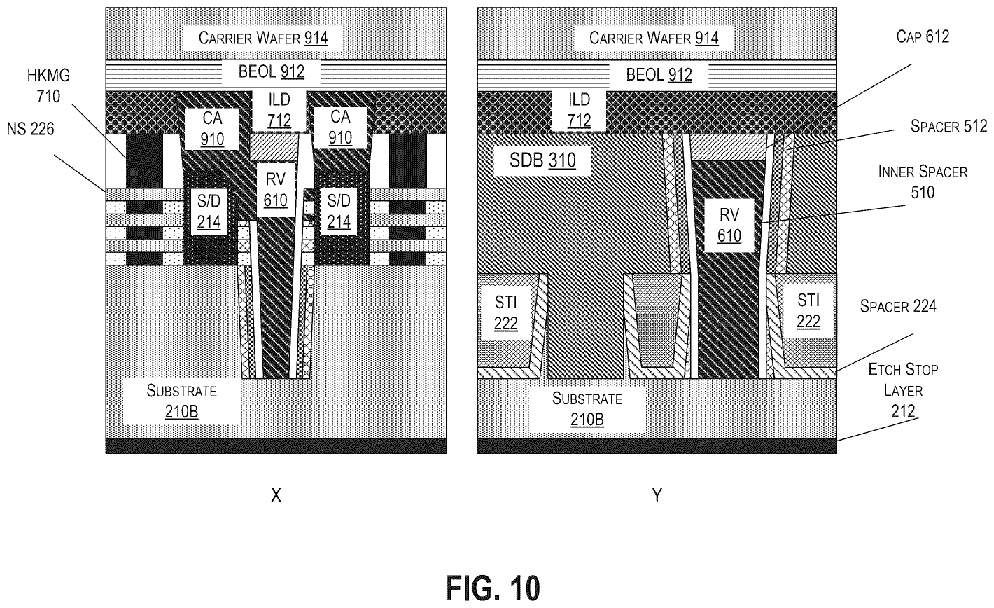

FIG. 10 illustrates the semiconductor device after the removal of the first substrate, in accordance with some embodiments. In some embodiments, the wafer is flipped and the first substrate is removed. The etching process can stop at the etch stop layer. It should be noted that, for the sake of simplicity, the semiconductor device is not shown as flipped.

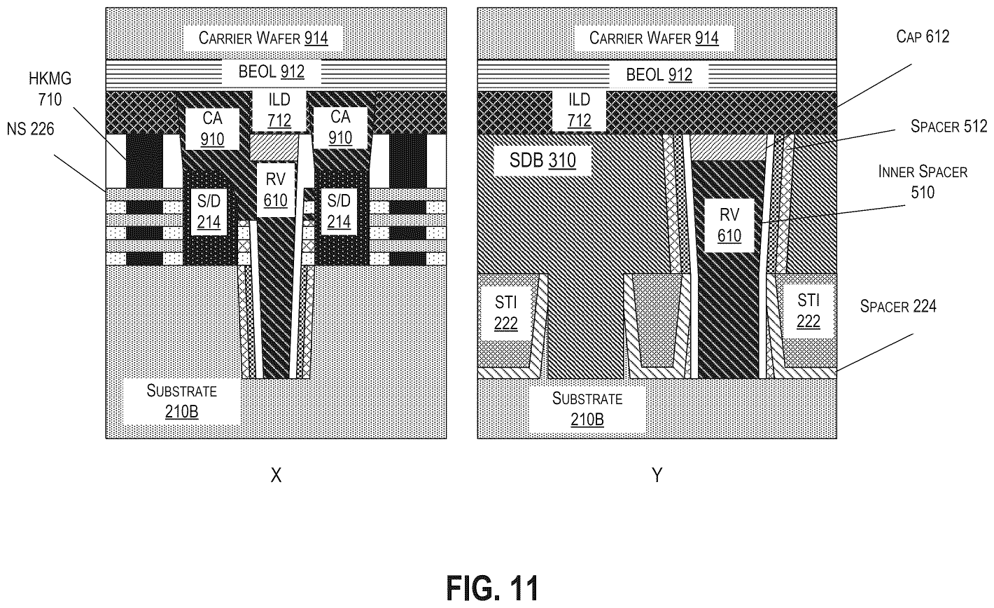

FIG. 11 illustrates the semiconductor device after the removal of the etch stop layer, in accordance with some embodiments. In some embodiments, the etch stop is removed and the second substrate 210B exposed.

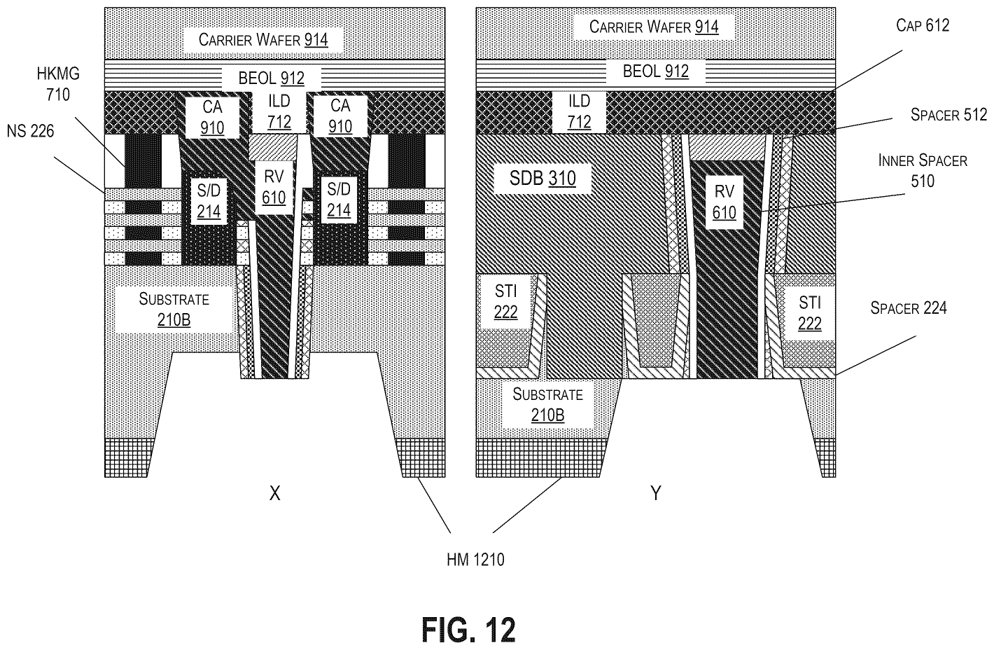

FIG. 12 illustrates a semiconductor device after the patterning of the backside via, in accordance with some embodiments. In some embodiments, portions of the second substrate 210B are removed to expose the backside of the RV 610. Prior to the removal, a hard mask, HM 1210, is formed over portions of the second substrate 210B which are not to be removed.

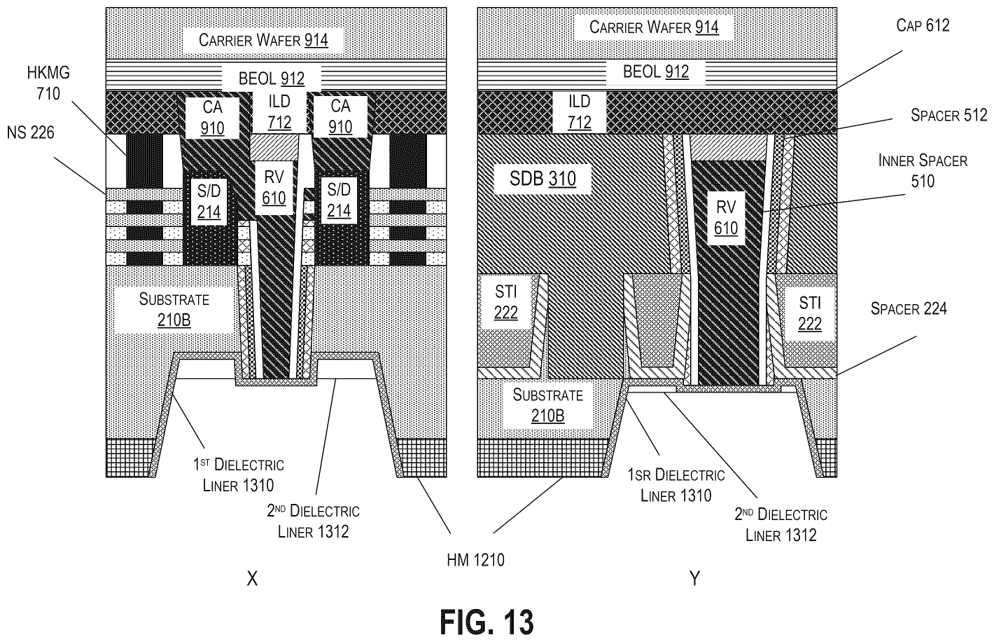

FIG. 13 illustrates a semiconductor device after the formation of dielectric liners, in accordance with some embodiments. In some embodiments, a first dielectric liner 1310 is formed over the exposed portions of the second substrate 210B and the RV 610. A second dielectric liner 1312 can be formed over portions of the first dielectric liner 1310.

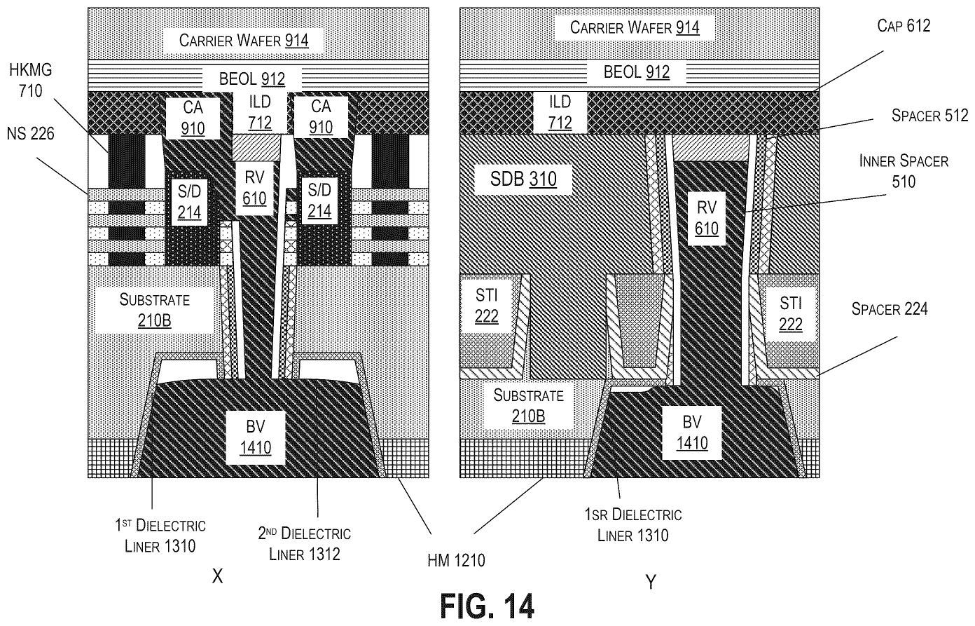

FIG. 14 illustrates a semiconductor device after the formation of the backside via, in accordance with some embodiments. In some embodiments, backside via, BV 1410, is formed to connect the CA 910 and the RV 610 to the BEOL 912. The BV 1410 can act as the backside part of the interconnect.

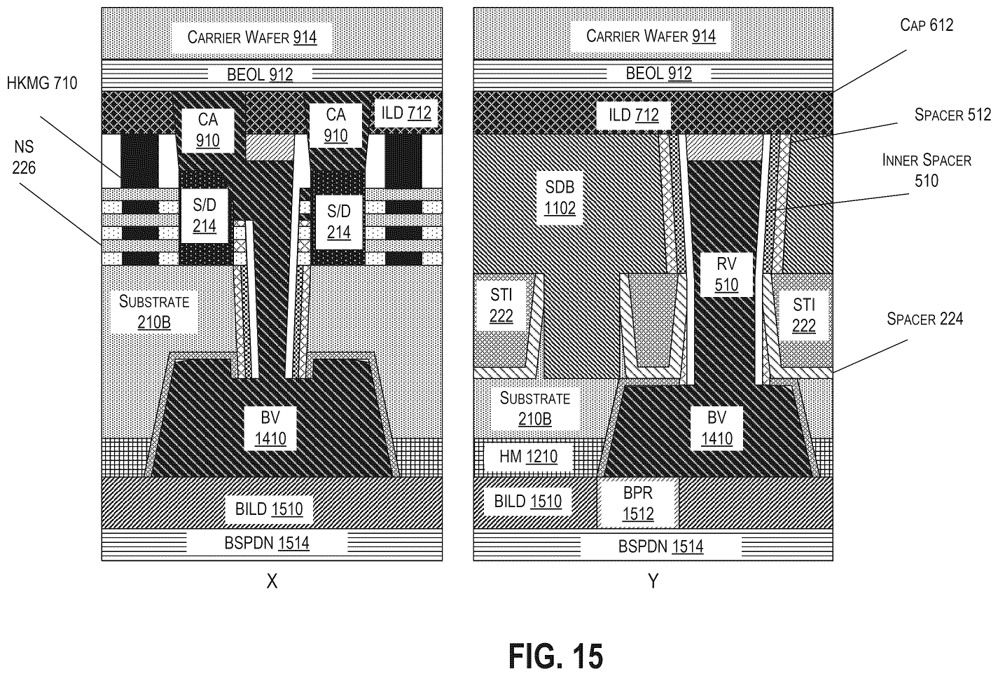

FIG. 15 illustrates a semiconductor device after the formation of the backside power delivery network, in accordance with some embodiments. In some embodiments, a bottom ILD, BILD 1510, is formed over the HM 1210 and the BV 1410. In several embodiments, the BILD 1510 can provide structural support to the semiconductor device by maintaining the mechanical integrity and stability of the semiconductor device. The BILD 151 can further help prevent the warping, bending, or cracking of the substrate, particularly during the manufacturing process or subsequent handling. The BILD 1510 can ensure that the semiconductor device remains mechanically robust and maintains its dimensional stability.

In an embodiment, the BILD 1510 can also serve as a planarization layer in the semiconductor device fabrication process. As various layers are deposited and patterned on the front side of the semiconductor device, irregularities or topographic variations may arise. The BILD 1510 can be used to smoothen the surface, creating a more planar substrate for subsequent processing steps, such as metal interconnect deposition or bonding. In some embodiments, a low dielectric constant BILD material can be utilized to reduce signal delays, crosstalk, and power consumption in high-speed and high-frequency circuits. By optimizing the dielectric constant, the BILD 1510 can contribute to improved overall semiconductor device performance. In several embodiments, BILD 1510 can facilitate wafer-level testing of the semiconductor device. By providing electrical isolation between the active regions and the backside contact, individual passive device or elements on the semiconductor device can be electrically accessed and tested without interference from neighboring devices or components. This enables efficient.

A backside power rail, BPR 1512, can be formed within the BILD 1510 and below the BV 1410. A backside power delivery network, BSPDN 1514, is formed over the BILD 1510 and the BPR 1512.

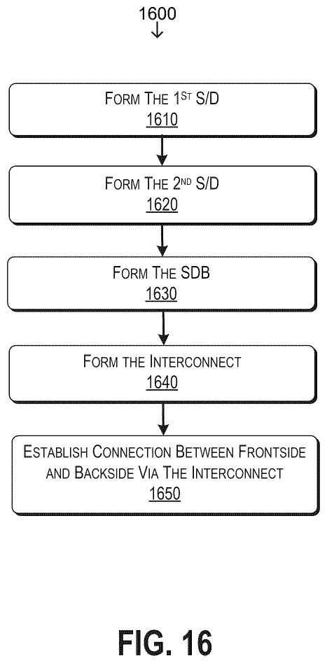

FIG. 16 illustrates a block diagram of a method 1600 for forming the semiconductor device, in accordance with some embodiments. As shown by block 1610, the first source/drain region is formed.

As shown by block 1620, the second source/drain region is formed.

As shown by block 1630, the single diffusion break is formed.

As shown by block 1640, the interconnect is formed within the single diffusion break.

As shown by block 1650, the electrical connection between the frontside of the semiconductor device and the backside of the semiconductor device is established via the interconnect.

In one aspect, the method and structures described above may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip may be mounted in a single chip package (such as a plastic carrier, with leads that are affixed to a motherboard or other higher-level carrier) or in a multichip package (such as a ceramic carrier that has either or both surface interconnections or buried interconnections). In any case, the chip can then be integrated with other chips, discrete circuit elements, and/or other signal processing devices as part of either (a) an intermediate product, such as a motherboard, or (b) an end product. The end product can be any product that includes integrated circuit chips, ranging from low-end applications, such as toys, to advanced computer products having a display, a keyboard or other input device, and a central processor.

### Conclusion

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications, and variations that fall within the true scope of the present teachings.

The components, steps, features, objects, benefits, and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, the inventive subject matter lies in less than all features of a single disclosed embodiment. Thus, the following claims are hereby incorporated into the Detailed Description, with each claim standing on its own as a separately claimed subject matter.

What is claimed is:

1. A semiconductor device, comprising:
a first source/drain region;
a second source/drain region;
a diffusion break between the first source/drain region and the second source/drain region; and
an interconnect within the diffusion break and configured to connect a back end of line (BEOL) in a frontside of the semiconductor device to a backside power delivery network (BSPDN) in a backside of the semiconductor device, the interconnect comprising:
a first vertical section;
a second vertical section connected to the first vertical section on an upper end of the second vertical section; and
a backside section connected to a lower end of the second vertical section, wherein the first vertical section is located on top of the first source/drain region.

2. The semiconductor device of claim 1, wherein:
the second vertical section extends from one side of the first source/drain region into the diffusion break, and
the backside section extends to the backside of the semiconductor device.

3. The semiconductor device of claim 1, wherein:
The first vertical section and the second vertical section are vertically offset from each other.

4. The semiconductor device of claim 1, further comprising:
shallow trench isolation (STI) on opposite sides of the second vertical section; and
a spacer isolating the diffusion break and the second vertical section.

5. The semiconductor device of claim 1, further comprising:
a cap layer over the second vertical section; and
an interlayer dielectric (ILD) isolating the cap layer and the diffusion break from contact with the BEOL.

6. The semiconductor device of claim 1, further comprising:
a bottom interlayer dielectric (BILD) isolating the BSPDN from contact with the interconnect; and
a backside power rail within the BILD and in contact with the BSPDN.

7. The semiconductor device of claim 1, further comprising:
a gate region; and
a plurality of alternating nanosheet gates extending horizontally across the gate region.

8. A method for fabrication of a semiconductor device, the method comprising:
forming a first source/drain region;
forming a second source/drain region;
forming a diffusion break between the first source/drain region and the second source/drain region;
forming an interconnect within the diffusion break; and
establishing a connection between a frontside of the semiconductor device and a backside of the semiconductor device via the interconnect.

9. The method of claim 8, wherein forming the interconnect comprises:
forming a first vertical section;
forming a second vertical section connected to the first vertical section on an upper end of the second vertical section; and
forming a backside section connected to a lower end of the second vertical section, wherein the first vertical section is located on top of the first source/drain region.

10. The method of claim 9, further comprising:
extending the second vertical section from one side of the first source/drain region into the diffusion break, and
extending the backside section to the backside of the semiconductor device.

11. The method of claim 9, wherein the first vertical section and the second vertical section are from each other.

12. The method of claim 9, further comprising:
forming shallow trench isolation (STI) on opposite sides of the second vertical section; and
isolating the diffusion break and the second vertical section via a spacer.

13. The method of claim 9, further comprising:
forming a cap layer over the second vertical section; and
isolating the cap layer and the diffusion break from contact with a back end of line (BEOL) via an interlayer dielectric (ILD).

14. The method of claim 8, further comprising:
isolating a backside power delivery network (BSPDN) from contact with the interconnect via a bottom interlayer dielectric (BILD); and
forming a backside power rail within the BILD and in contact with the BSPDN.

15. The method of claim 9, further comprising:
forming a gate region; and
forming a plurality of alternating nanosheet gates extending horizontally across the gate region.

16. A semiconductor device, comprising:
a first source/drain region;
a second source/drain region;
a single diffusion break (SDB) between the first source/drain region and the second source/drain region; and
a frontside via within the SDB, wherein:
one side of frontside via is connected to a frontside contact over the first source/drain region, and
the frontside via is connected to a backside power delivery network (BSPDN).

17. The semiconductor device of claim 16, wherein the frontside via is connected to the BSPDN through a backside via and a backside power rail (BPR).

18. The semiconductor device of claim 16, further comprising:
shallow trench isolation (STI) on opposite sides of the frontside via; and
a spacer isolating the SDB and the frontside via.

19. The semiconductor device of claim 16, further comprising:
a cap layer over the frontside via; and
an interlayer dielectric (ILD) isolating the cap layer and the SDB from contact with a back end of line (BEOL).

20. The semiconductor device of claim 16, further comprising:
a bottom interlayer dielectric (BILD) isolating the BSPDN from contact with the frontside via; and
a backside power rail within the BILD and in contact with the BSPDN.
